(19) United States
(12) Patent Application Publication
(10) Pub. No.: US 2026/0032942 A1
(43) Pub. Date: Jan. 29, 2026

(54) HIGH ELECTRON MOBILITY TRANSISTOR

(71) Applicant: NATIONAL YANG MING CHIAO TUNG UNIVERSITY, Hsinchu City (TW)

(72) Inventors: Edward YI CHANG, Hsinchu City (TW); You-Chen WENG, Hsinchu City (TW); Tsung-Han CHIANG, Hsinchu City (TW); Chih-Yi YANG, Hsinchu City (TW)

(21) Appl. No.: 19/058,110

(22) Filed: Feb. 20, 2025

(30) Foreign Application Priority Data
Jul. 23, 2024 (TW) 113127442

(51) Int. Cl. H10D 30/47; H01L 23/29; H01L 23/31; H10D 62/85

(52) U.S. Cl. CPC H10D 30/475; H01L 23/291; H01L 23/3171; H10D 62/8503

(57) ABSTRACT

A high electron mobility transistor includes a substrate, a barrier layer, a semiconductor layer and an insertion layer. The barrier layer is disposed on the substrate and includes aluminum gallium indium nitride. The semiconductor layer is disposed between the substrate and the barrier layer. The insertion layer is disposed between the semiconductor layer and the barrier layer, and includes aluminum gallium nitride.

### CROSS-REFERENCE TO RELATED APPLICATIONS

This application claims the benefits of the Taiwan Patent Application Serial Number 113127442, filed on Jul. 23, 2024, the subject matter of which is incorporated herein by reference.

### BACKGROUND OF THE INVENTION

### Field

The present invention relates to a high electron mobility transistor.

More specifically, the present invention relates to a gallium nitride (GaN) high electron mobility transistor.

### Description of Related Art

High electron mobility transistors (HEMTs) have gradually attracted attention from various fields in recent years. HEMTs have the advantages of fast switching speed, high electron mobility, high collapse electric field, good thermal stability and wide energy gap, and can be used in high-voltage electronic components or high-frequency electronic components.

The current high electron mobility transistors use GaN as the channel layer, and a ternary or quaternary barrier layer is formed on the channel layer. However, due to issues such as lattice mismatch and growth temperature differences between the barrier layer and the channel layer, the epitaxial quality often deteriorates and leakage current increases, thereby affecting the performance of the transistor.

Therefore, in order to cope with the application of radio frequency power components in the future, it is desirable to propose an improved high electron mobility transistor to further improve the component current and output power and eliminate or alleviate the above problems.

### SUMMARY OF THE INVENTION

The present invention provides a high electron mobility transistor with an insertion layer between the barrier layer and the channel layer of the semiconductor layer, and the insertion layer includes aluminum gallium nitride (AlGaN). The insertion layer acts as an intermediary, thereby improving the lattice matching or improving the quality of the barrier layer, resulting in a smoother interface and enhanced structural integrity. In addition, the setting of the insertion layer can also significantly improve the surface roughness, electron mobility, polarization of two-dimensional electron gas (2DEG), or reduce the generation of leakage current, which can significantly enhance the performance of the high electron mobility transistor.

In view of this, according to one aspect of the present invention, a high electron mobility transistor is provided, which comprises a substrate, a barrier layer, a semiconductor layer and an insertion layer. The barrier layer is disposed on the substrate, and the barrier layer comprises aluminum gallium indium nitride (InAlGaN). The semiconductor layer is disposed between the substrate and the barrier layer. The insertion layer is disposed between the semiconductor layer and the barrier layer, and comprises aluminum gallium nitride (AlGaN).

In the present invention, the substrate may be a quartz substrate, a glass substrate, a silicon substrate, a sapphire substrate, a silicon carbide substrate, a GaN substrate or a combination thereof. For example, the substrate is a silicon substrate.

In the present invention, aluminum gallium indium nitride (InAlGaN) may be In_{1-x-y}AlₓGa_{y}N, wherein x may be between 0.1 and 0.8, and y may be between 0.8 and 0.1.

In the present invention, a thickness of the barrier layer may range from 3 nm to 40 nm, for example, from 3 nm to 35 nm, from 3 nm to 30 nm, from 3 nm to 25 nm, from 3 nm to 20 nm, from 3 nm to 15 nm, from 3 nm to 10 nm, from 5 nm to 40 nm, from 5 nm to 35 nm, from 5 nm to 30 nm, from 5 nm to 20 nm, from 5 nm to 15 nm or about 6 nm.

In the present invention, the semiconductor layer may comprise a nucleation layer, a buffer layer and a GaN layer. The GaN layer may be disposed on the nucleation layer, and the buffer layer may be disposed between the nucleation layer and the GaN layer. The nucleation layer may comprise aluminum nitride (AlN), and the buffer layer may comprise aluminum gallium nitride (AlGaN) and gallium nitride (GaN). In addition, the thickness of the nucleation layer may range from 50 nm to 300 nm, for example, from 50 nm to 250 nm, from 50 nm to 200 nm, from 50 nm to 150 nm, or about 100 nm. The thickness of the buffer layer may range from 50 nm to 5000 nm, for example, from 50 nm to 4000 nm, from 50 nm to 3000 nm, from 50 nm to 2000 nm, about 200 nm or about 2500 nm.

In the present invention, the thickness of the insertion layer may range from 1 nm to 15 nm, for example, from 1 nm to 12 nm, from 1 nm to 10 nm, from 1 nm to 8 nm, from 1 nm to 5 nm, from 1 nm to 3 nm, about 1 nm or about 2 nm.

In the present invention, AlGaN may be Al_{z}Ga_{l-z}N, and z may be between 0.1 and 0.8. For example, z may be between 0.1 and 0.7, between 0.1 and 0.6, between 0.1 and 0.5, between 0.1 and 0.4, between 0.1 and 0.3, between 0.2 and 0.7, between 0.2 and 0.6, between 0.2 and 0.5, between 0.2 and 0.4, about 0.15 or about 0.22.

In the present invention, the high electron mobility transistor may further comprise a passivation layer disposed on the barrier layer, wherein the passivation layer may comprise silicon nitride.

In the present invention, the high electron mobility transistor may further comprise a drain electrode, a source electrode and a gate electrode, wherein the drain electrode and the source electrode may be disposed on the barrier layer, and the gate electrode may be disposed on the passivation layer.

In the present invention, the material of the drain electrode, the source electrode and the gate electrode may respectively be copper, aluminum, molybdenum, tungsten, gold, chromium, nickel, platinum, titanium, copper alloy, aluminum alloy, molybdenum alloy, tungsten alloy, gold alloy, chromium alloy, nickel alloy, platinum alloy, titanium alloy, other suitable metals, or a combination thereof. In addition, the drain electrode, the source electrode and the gate electrode may comprise single or multiple metal layers.

Other objects, advantages, and novel features of the disclosure will become more apparent from the following detailed description when taken in conjunction with the accompanying drawings.

### BRIEF DESCRIPTION OF DRAWINGS

FIG. 1 is a schematic view showing a high electron mobility transistor of the present invention.

FIG. 2 is an AFM photo of Embodiment 1.

FIG. 3 is an AFM photo of Comparative embodiment 2.

FIG. 4 is an energy band diagram of Embodiment 1, Comparative embodiment 1 and Comparative embodiment 2 of the present invention.

FIG. 5 is an Ip-VG plot of Embodiment 1, Comparative embodiment 1 and Comparative embodiment 2 of the present invention.

FIG. 6 is an Ip-VD plot of Embodiment 1, Comparative embodiment 1 and Comparative embodiment 2 of the present invention.

FIG. 7 is a C-V plot of Embodiment 1 and Comparative embodiment 2 of the present invention.

### DETAILED DESCRIPTION OF THE INVENTION

Different embodiments of the present invention are provided in the following description. These embodiments are meant to explain the technical content of the present invention, but not meant to limit the scope of the present invention. A feature described in an embodiment may be applied to other embodiments by suitable modification, substitution, combination, or separation.

It should be noted that, in the present specification, when a component is described to have an element, it means that the component may have one or more of the elements, and it does not mean that the component has only one of the element, except otherwise specified.

Moreover, in the present specification, the terms, such as “top”, “bottom”, “left”, “right”, “front”, “back”, or “middle”, as well as the terms, such as “on”, “above”, “under”, “below”, or “between”, are used to describe the relative positions among a plurality of elements, and the described relative positions may be interpreted to include their translation, rotation, or reflection.

Moreover, in the present specification, when an element is described to be arranged “on” another element, it does not essentially mean that the elements contact the other element, except otherwise specified. Such interpretation is applied to other cases similar to the case of “on”.

Moreover, in the present specification, a value may be interpreted to cover a range within ±10% of the value, and in particular, a range within ±5% of the value, except otherwise specified; a range may be interpreted to be composed of a plurality of subranges defined by a smaller endpoint, a smaller quartile, a median, a greater quartile, and a greater endpoint, except otherwise specified.

### Embodiment 1

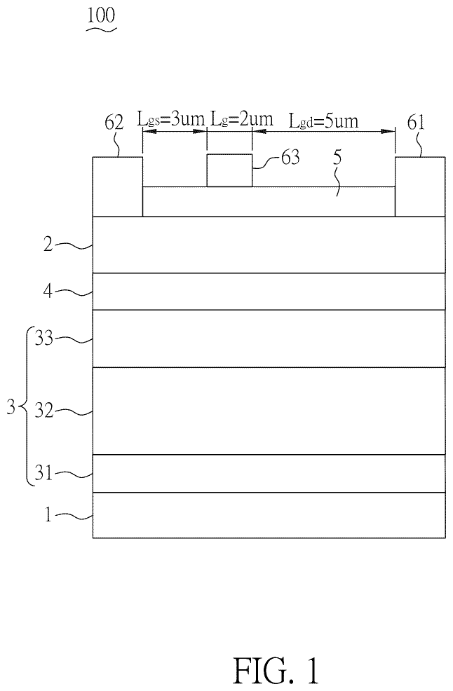

FIG. 1 is a schematic view showing a high electron mobility transistor according to Embodiment 1 of the present invention.

As shown in FIG. 1, the high electron mobility transistor 100 of the present embodiment comprises: a substrate 1, a barrier layer 2, a semiconductor layer 3, an insertion layer 4, a passivation layer 5, a drain electrode 61, a source electrode 62 and a gate electrode 63. The barrier layer 2 is disposed on the substrate 1 and comprises aluminum gallium indium nitride (InAlGaN). The semiconductor layer 3 is disposed between the substrate 1 and the barrier layer 2 and comprises a nucleation layer 31, a buffer layer 32 and a GaN layer 33, wherein the GaN layer 33 is disposed on the nucleation layer 31, the buffer layer 32 is disposed between the nucleation layer 31 and the GaN layer 33, and the nucleation layer 31 comprises aluminum nitride (AlN). The insertion layer 4 is disposed between the semiconductor layer 3 and the barrier layer 2, and the insertion layer 4 comprises aluminum gallium nitride (AlGaN). In addition, the passivation layer 5 is disposed on the barrier layer 2 and comprises silicon nitride. The drain electrode 61 and the source electrode 62 are disposed on the barrier layer 2, and the gate electrode 63 is disposed on the passivation layer 5.

The method for manufacturing the high electron mobility transistor 100 of the present embodiment comprises the following steps. A silicon substrate 1 is provided, and a nucleation layer 31 comprising 100 nm AlN, a buffer layer 32 comprising 200 nm Al_{0.15}Ga_{0.85}N and 2.5 μm carbon-doping GaN and a GaN layer 33 comprising 500 nm GaN are sequentially grown on the silicon substrate 1 through metal-organic chemical vapor deposition (MOCVD) to form the semiconductor layer 3. Next, an insertion layer 4 comprising 2 nm Al_{0.15}Ga_{0.85}N and a barrier layer 2 comprising 6 nm In_{0.04}Al_{0.66}Ga_{0.3}N are sequentially formed on the semiconductor layer 3. An electron gun is used to deposit 200 Å Ti/1200 Å Al/250 Å Ni/1000 Å Au metal layers as a drain electrode 61 and a source electrode 62 on the barrier layer 2. After removing the remaining part and annealing in a nitrogen environment at 820° C., the passivation layer 5 comprising 25 nm SiN is deposited using atomic layer deposition (ALD) and rapid thermal annealing (RTA) is performed at 300° C. Next, an electron gun is used to form 500 Å Ni/3000 Å Au metal layers as the gate electrode 63. Finally, etching is performed by chlorine inductively coupled plasma (ICP) to obtain the high electron mobility transistor 100. The gate length L_{g} of the gate electrode is 2 μm, the distance L_{gs} between the gate electrode and the source electrode is 3 μm, and the distance L_{gd} between the gate electrode and the drain electrode is 5 μm.

### Embodiment 2

The HEMT of the present embodiment is similar to that of Embodiment 1, except that the insertion layer 4 of the present embodiment comprises 4 nm Al_{0.15}Ga_{0.85}N.

### Embodiment 3

The HEMT of the present embodiment is similar to that of Embodiment 1, except that the insertion layer 4 of the present embodiment comprises 6 nm Al_{0.15}Ga_{0.85}N.

### Embodiment 4

The HEMT of the present embodiment is similar to that of Embodiment 3, except that the barrier layer 2 of the present embodiment comprises 4 nm In_{0.04}Al_{0.66}Ga_{0.3}N.

### Embodiment 5

The HEMT of the present embodiment is similar to that of Embodiment 1, except that the barrier layer 2 of the present embodiment comprises 7 nm In_{0.04}Al_{0.66}Ga_{0.3}N.

### Embodiment 6

The HEMT of the present embodiment is similar to that of Embodiment 1, except that the insertion layer 4 of the present embodiment comprises 2 nm Al_{0.22}Ga_{0.78}N.

### Comparative Embodiment 1

The HEMT of Comparative embodiment 1 is similar to that of Embodiment 1, except that the insertion layer 4 of Comparative embodiment 1 comprises 1 nm AlN.

### Comparative Embodiment 2

The HEMT of Comparative embodiment 2 is similar to that of Embodiment 1, except that the HEMT of Comparative embodiment 2 does not comprise the insertion layer 4.

### Comparative Embodiment 3

The HEMT of Comparative embodiment 3 is similar to that of Embodiment 1, except that the insertion layer 4 of Comparative embodiment 3 comprises 2 nm AlN.

### Comparative Embodiment 4

The HEMT of Comparative embodiment 4 is similar to that of Comparative embodiment 3, except that the barrier layer 2 of Comparative embodiment 4 comprises 23 nm Al_{0.2}Ga_{0.8}N.

### Experimental Results

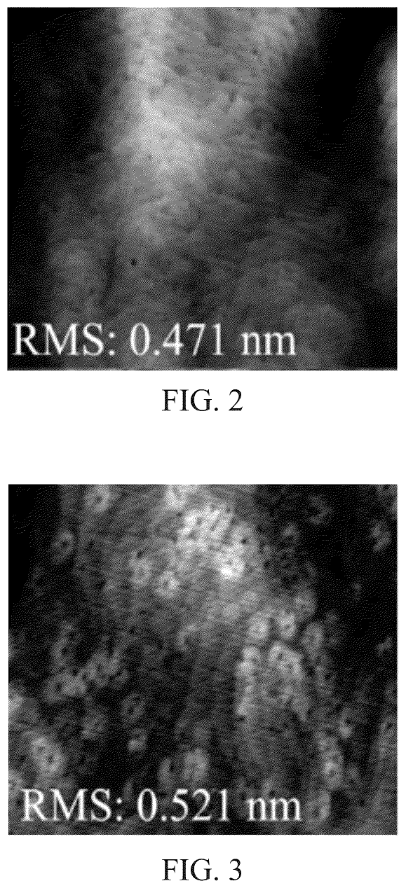

FIG. 2 is an AFM photo of Embodiment 1.

FIG. 3 is an AFM photo of Comparative embodiment 2.

As shown in FIG. 1 to FIG. 3, in the high electron mobility transistor 100 of Embodiment 1, the insertion layer 4 is an intermediary between the GaN layer 33 and the barrier layer 2, and the lattice constant thereof is much closer between the GaN layer 33 and the barrier layer 2. Therefore, the epitaxial quality and surface morphology can be significantly improved. In addition, the interface between the insertion layer 4 and the GaN layer 33 is smoother, which can reduce the binding energy of indium atoms and improve the growth of the barrier layer 2.

In addition, the surface roughness (RMS) of the barrier layer 2 of the high electron mobility transistor 100 of Embodiment 1 is 0.471 nm, the surface roughness of the barrier layer 2 of the high electron mobility transistor 100 of Embodiment 2 is 0.383 nm, and the surface roughness of the barrier layer 2 of the high electron mobility transistor 100 of Embodiment 3 is 0.357 nm. As the thickness of the insertion layer 4 increases, the epitaxial quality can be improved due to longer migration length and growth time. However, the roughness of the barrier layer 2 of the Comparative embodiment 2 is 0.521 nm and the barrier layer 2 has more pits and hillocks, resulting in the interface and quality problem. Thus, compared with Comparative embodiment 2, the high electron mobility transistors 100 of Embodiment 1, Embodiment 2 and Embodiment 3 has lower interface scattering due to improved epitaxial quality and alloy scattering, which helps to achieve better electron mobility.

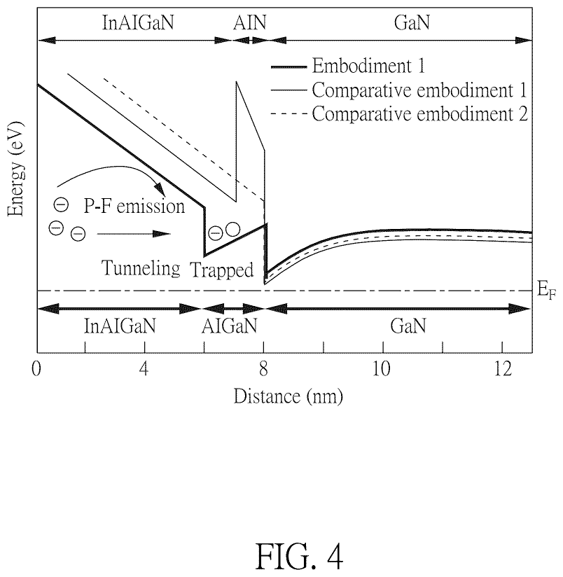

FIG. 4 is an energy band diagram of Embodiment 1, Comparative embodiment 1 and Comparative embodiment 2 of the present invention.

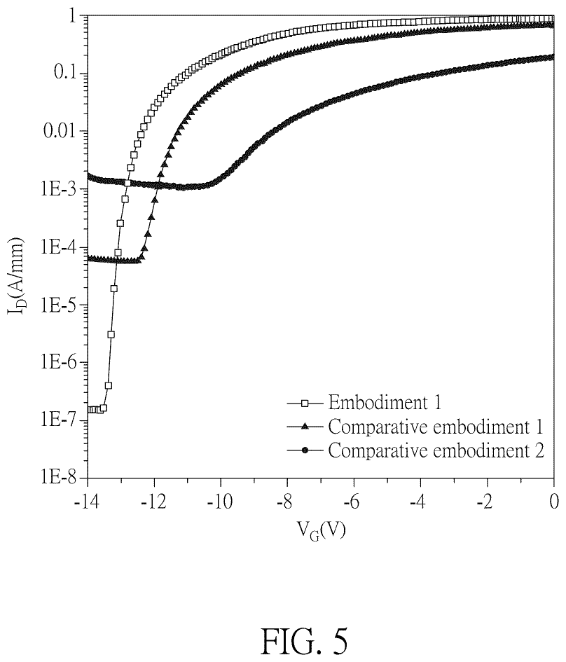

FIG. 5 is an I_{D}-V_{G} plot of Embodiment 1, Comparative embodiment 1 and Comparative embodiment 2 of the present invention.

Please refer to FIG. 1, FIG. 4 and FIG. 5. The leakage mechanism is studied through the energy band diagram. The insertion layer 4 of the high electron mobility transistor 100 of Embodiment 1 forms an additional quantum well through the hetero-structure of the barrier layer 2 and the GaN layer 33 to effectively trap electrons during the off-state. This plays a crucial role in mitigating gate electrode leakage current. In addition, compared with the results of Comparative embodiment 1 and Comparative embodiment 2, the insertion layer 4 of the high electron mobility transistor 100 of Embodiment 1 shows a flatter conduction band slope, which prevents electrons from passing through the barrier and the dielectric interface. In addition, an additional quantum well is formed at the interface between the barrier layer 2 and the insertion layer 4, introducing an extra barrier height, thereby hindering the electron movement and promoting the trapping of electrons. Therefore, the off-state leakage current of the high electron mobility transistor 100 of Embodiment 1 is low (as shown in FIG. 5).

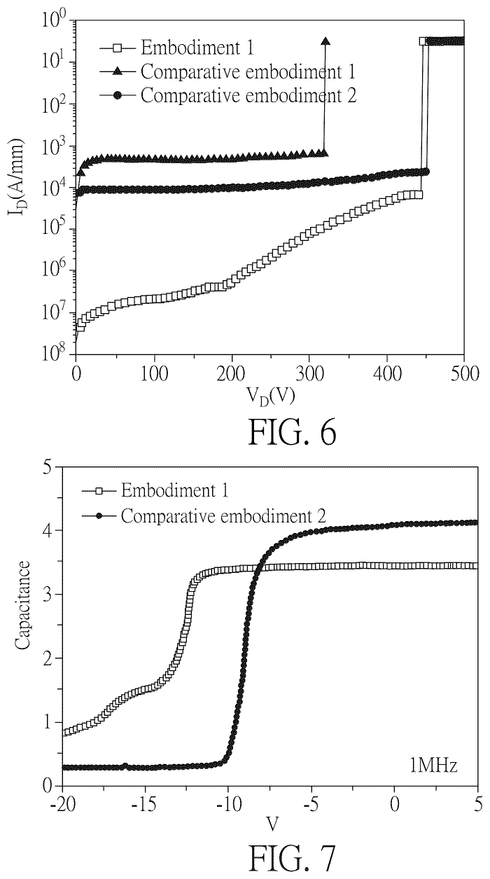

FIG. 6 is an I_{D}-V_{D} plot of Embodiment 1, Comparative embodiment 1 and Comparative embodiment 2 of the present invention.

FIG. 7 is a C-V plot of Embodiment 1 and Comparative embodiment 2 of the present invention.

As shown in FIG. 1 and FIG. 6, compared with Comparative embodiment 1, by optimizing epitaxy and introducing an additional quantum well, the leakage current of the high electron mobility transistor 100 of Embodiment 1 has been significantly reduced by two orders of magnitude. In addition, the breakdown voltage of the high electron mobility transistor 100 of Embodiment 1 reaches 450V, which is an increase of 120V compared with Comparative embodiment 1. Furthermore, as shown in FIG. 1 and FIG. 7, the insertion layer 4 of the high electron mobility transistor 100 of Embodiment 1 introduces additional capacitance, leading to an overall decrease in total capacitance due to the reciprocal relationship involved in summing individual capacitances. Furthermore, at a gate electrode voltage of −18 V, an additional slope in the capacitance curve becomes apparent. This phenomenon is attributed to the release of electrons previously trapped at the hetero-junction between the barrier layer 2 and the insertion layer 4 during the formation of the additional quantum well. In the gate electrode voltage range of −20 to −15 V, the presence of trapped electrons affects the capacitance slope. As more positive gate electrode voltage is applied, the capacitance curve exhibits another slope related to channel behavior, similar to the trend observed for Comparative embodiment 2.

The results of sheet resistance, electron mobility and carrier density of Embodiment 1, Embodiment 2, Embodiment 5, Embodiment 6 and Comparative embodiment 4 are shown in Table 1 below.

TABLE 1

| | Sheet | Electron | Carrier | Maximum drain |
|---|---|---|---|---|
| | resistance | mobility | density | electrode current |
| | (Ω/□) | (cm²/V-s) | (10¹³ cm⁻²) | (mA/mm) |
| Embodiment 1 | 330 | 1450 | −1.30 | 1228 |
| Embodiment 2 | 289 | 1590 | −1.36 | 1280 |
| Embodiment 5 | 376 | 1210 | −1.40 | 1560 |
| Embodiment 6 | 276 | 1500 | −1.51 | — |
| Comparative | 420 | 1600 | −0.95 | — |
| embodiment 4 | | | | |

From the results in Table 1 and FIG. 1, the high electron mobility transistors 100 of Embodiment 1, Embodiment 2, Embodiment 5 and Embodiment 6 have better sheet resistance. As the thickness of the insertion layer 4 increases, greater piezoelectric polarization will be generated to generate more electrons and better epitaxial quality, which will facilitate reducing sheet resistance and maintain high electron mobility and high carrier density. This results in high drain electrode current, which helps enhance the performance of the high electron mobility transistor 100.

In summary, the high electron mobility transistor of the present invention can improve epitaxial quality, enhance electronic performance, or reliability. In addition, the high electron mobility transistor of the present invention can also improve the polarization of the two-dimensional electron gas or reduce the leakage current, and alleviate the problem of the leakage current by forming an additional quantum well in the hetero-structure of the barrier layer and the insertion layer. On the other hand, the high electron mobility transistor of the present invention can reduce interface scattering, thereby improving the overall epitaxial quality.

Although the present disclosure has been explained in relation to its embodiment, it is to be understood that many other possible modifications and variations can be made without departing from the spirit and scope of the disclosure as hereinafter claimed.

1. A high electron mobility transistor, comprising:
a substrate;
a barrier layer disposed on the substrate and comprising aluminum gallium indium nitride;
a semiconductor layer disposed between the substrate and the barrier layer; and
an insertion layer disposed between the semiconductor layer and the barrier layer and comprising aluminum gallium nitride.

2. The high electron mobility transistor of claim 1, wherein a thickness of the barrier layer ranges from 3 nm to 40 nm.

3. The high electron mobility transistor of claim 1, wherein the semiconductor layer comprises a nucleation layer, a buffer layer and a gallium nitride layer, the gallium nitride layer is disposed on the nucleation layer, and the buffer layer is disposed between the nucleation layer and the gallium nitride layer.

4. The high electron mobility transistor of claim 3, wherein the nucleation layer comprises aluminum nitride.

5. The high electron mobility transistor of claim 1, wherein a thickness of the insertion layer ranges from 1 nm to 15 nm.

6. The high electron mobility transistor of claim 1, wherein the aluminum gallium nitride is Al_{z}Ga_{1-z}N, and z is between 0.1 and 0.8.

7. The high electron mobility transistor of claim 6, wherein z is between 0.1 and 0.3.

8. The high electron mobility transistor of claim 1, further comprising a passivation layer disposed on the barrier layer.

9. The high electron mobility transistor of claim 1, wherein the passivation layer comprises silicon nitride.

10. The high electron mobility transistor of claim 8, further comprising a drain electrode, a source electrode and a gate electrode, wherein the drain electrode and the source electrode are disposed on the barrier layer, and the gate electrode is disposed on the passivation layer.
